(19) United States
(12) Patent Application Publication
(10) Pub. No.: US 2024/0167156 A1
(43) Pub. Date: May 23, 2024

(54) FLUIDIC BAFFLE FOR HIGH PRESSURE FLUID DISTRIBUTION AND SUBSTRATE PROCESSING APPARATUS

(71) Applicants: SEMES CO., LTD., Cheonan-si (KR); Samsung Electronics Co., Ltd., Suwon-si (KR)

(72) Inventors: Hyungseok KANG, Cheonan-si (KR); Joonho WON, Cheonan-si (KR); Pilkyun HEO, Cheonan-si (KR); Hongchan CHO, Cheonan-si (KR); Ilyoung KIM, Cheonan-si (KR); Sangjine PARK, Suwon-si (KR); Seungmin SHIN, Suwon-si (KR); Jihwan PARK, Suwon-si (KR); Kuntack LEE, Suwon-si (KR)

(73) Assignees: SEMES CO., LTD., Cheonan-si (KR); Samsung Electronics Co., Ltd., Suwon-si (KR)

(21) Appl. No.: 18/474,738

(22) Filed: Sep. 26, 2023

(30) Foreign Application Priority Data
Nov. 16, 2022 (KR) 10-2022-0153259

(51) Int. Cl. C23C 16/455; G03F 7/00; H01J 37/32

(52) U.S. Cl. CPC C23C 16/45565; C23C 16/45568; G03F 7/70033; H01J 37/32449

(57) ABSTRACT

A substrate processing apparatus includes a chamber configure to provide a space for processing a substrate, a substrate support configured to support the substrate in the chamber, an upper supply port provided in an upper portion of the chamber and configured to supply a supercritical fluid on an upper surface of the substrate, a recess provided in an upper wall of the chamber and having a diffuser shape whose diameter gradually increases from an outlet of the upper supply port, and a fluidic baffle disposed in the recess between the upper supply port and the substrate and including unit cells repeatedly arranged in a space with same phases and geometric sizes and in fluid communication with each other.

### CROSS-RELATED APPLICATION

This application claims priority under 35 USC § 119 to Korean Patent Application No. 10-2022-0153259, filed on Nov. 16, 2022 in the Korean Intellectual Property Office (KIPO), the contents of which are herein incorporated by reference in their entirety.

### BACKGROUND

### 1. Field

Example embodiments relate to a fluidic baffle for high pressure fluid distribution and a substrate processing apparatus including the same. More particularly, example embodiments relate to a fluidic baffle configured to distribute a high-pressure supercritical fluid on a surface of a substrate for drying the substrate and a substrate processing apparatus including the same.

### 2. Description of the Related Art

After performing a development process of an EUV photoresist layer on a substrate, a drying process using a supercritical fluid may be performed to dry the substrate including a developer coated thereon. In a substrate processing apparatus using such a supercritical fluid, the high pressure supercritical fluid may be supplied to an upper surface of the substrate at a high speed from a fluid supply port having a relatively small diameter. When the fluid having the high speed collides with the substrate, a chemical solution applied on the substrate may be instantaneously pushed out and the substrate may be dried in a state where a density of the fluid is not sufficiently high, which may cause defects such as pattern collapse.

### SUMMARY

Example embodiments provide a fluidic baffle for high pressure fluid distribution that is capable of evenly distributing a high pressure fluid on a surface of a substrate.

Example embodiments provide a substrate processing apparatus including the fluidic baffle.

According to example embodiments, a fluidic baffle includes an upper baffle having a first cone shape, and a lower baffle integrally formed with the upper baffle and having a second cone shape. Each of the upper baffle and the lower baffle has a three-dimensional curved structure where an interior is divided into two subspaces twisted with each other by an interface and having triperiodic minimum curved surface (TPMS).

According to example embodiments, a substrate processing apparatus includes a chamber configure to provide a space for processing a substrate, a substrate support configured to support the substrate in the chamber, an upper supply port provided in an upper portion of the chamber and configured to supply a supercritical fluid on an upper surface of the substrate, a recess provided in an upper wall of the chamber and having a diffuser shape whose diameter gradually increases from an outlet of the upper supply port, and a fluidic baffle disposed in the recess between the upper supply port and the substrate and including unit cells repeatedly arranged in a space with same phases and geometric sizes and in fluid communication with each other.

According to example embodiments, a substrate processing apparatus includes a chamber including an upper chamber and a lower chamber that are engageable with each other and provide a space for processsing a substrate, a substrate support configured to support the substrate in the chamber, an upper supply port disposed in the upper chamber and configured to supply a supercritical fluid on an upper surface of the substrate in the chamber, a recess provided in an lower surface of the upper chamber and having a diffuser shape whose diameter gradually increases from an outlet of the upper supply port, and a fluidic baffle disposed in the recess between the upper supply port and the substrate and having a three-dimensional curved structure where an interior is divided into two subspaces twisted with each other by an interface and having triperiodic minimum curved surface (TPMS).

According to example embodiments, a substrate processing apparatus includes a chamber including an upper chamber and a lower chamber that are engageable with each other and provide a space for processsing a substrate, a substrate support configured to support the substrate in the chamber, an upper supply port provided in the upper chamber and configured to supply a supercritical fluid on an upper surface of the substrate in the chamber, an exhaust port provided in a lower portion of the chamber and configured to exhaust the fluid in the chamber, a lower supply port provided in the lower portion of the chamber as adjacent to the exhaust port and configured to supply a supercritical fluid into the chamber, a recess provided in an lower surface of the upper chamber and having a diffuser shape whose diameter gradually increases from an outlet of the upper supply port and a fluidic baffle disposed in the recess between the upper supply port and the substrate and including unit cells repeatedly arranged in a space and in fluid communication with each other. Each of the unit cells includes upper holes disposed in a first plane and which fluid enters, lower holes disposed in a second plane parallel with the first plane and spaced apart from the first plane along a vertical direction, an crossover passage hole disposed between the first plane and the second plane and branch passages extending along oblique directions between the first plane and the second plane and including upper branch passages communicating the upper holes with the crossover passage hole, respectively and lower branch passages communicating the crossover passage hole with the lower holes, respectively.

According to example embodiments, a fluidic baffle for high pressure fluid distribution may include a fluid pipe having oblique passages that extend along oblique directions. After fluid having a relatively high pressure enters the fluidic baffle, the fluid may move from an overlying lattice layer to an underlying lattice layer along the oblique passages.

The fluid pipe of the fluidic baffle may have a spherical shape and may include an upper hole, a crossover passage hole and a lower hole in fluid communication with each other through the oblique passages. Since the upper hole, the crossover passage hole, the lower hole and the oblique passages have different diameters, when the fluid passes through the fluid pipe of the fluidic baffle, a surge pressure of the supercritical fluid may be repeatedly dissipated as kinetic energy due to an increased pressure loss.

Accordingly, the fluidic baffle may serve as an inertia relief member for relieving a flow rate of the fluid supplied from an upper portion of the chamber toward the substrate. Thus, in a process of drying a developer using a supercritical fluid after treating the developer during a semiconductor photo process, an inertial force exerted on the upper surface of the substrate by the supercritical fluid may be reduced to prevent damages such as collapse of a pattern on the substrate.

### BRIEF DESCRIPTION OF THE DRAWINGS

FIG. 1 is a plan view illustrating a substrate processing system in accordance with example embodiments.

FIG. 2 is a cross-sectional view illustrating a substrate processing apparatus in accordance with example embodiments.

FIG. 3 is a cross-sectional view illustrating a chamber of the substrate processing apparatus in FIG. 2, wherein the chamber is an open state.

FIG. 4 is a perspective view illustrating a substrate support of the substrate processing apparatus in FIG. 2.

FIG. 5 is a block diagram illustrating a fluid supply of the substrate processing apparatus in FIG. 2.

FIG. 6 is a graph illustrating a pressure change within a chamber during performing the drying process by the substrate processing apparatus in FIG. 2.

FIG. 7 is a cross-sectional view illustrating a fluidic baffle installed in the substrate processing apparatus in FIG. 2.

FIG. 8 is a perspective view illustrating the fluidic baffle in FIG. 7.

FIG. 9 is a perspective view illustrating a portion of the fluidic baffle in FIG. 7.

FIG. 10 is a perspective view illustrating a unit cell of the fluidic baffle of FIG. 7.

FIG. 11 is a cross-sectional view illustrating a fluid passage of the unit cell in FIG. 10.

FIG. 12 is a view illustrating fluid flow in the unit cell in FIG. 10.

FIG. 13 is a view illustrating fluid flow in a portion of the fluidic baffle of FIG. 7.

FIG. 14 is a perspective view illustrating a portion of a fluidic baffle for high pressure fluid distribution in accordance with example embodiments.

FIG. 15 is a perspective view illustrating unit cells of the fluidic baffle in FIG. 14.

FIGS. 16A to 16E are perspective views taken along the lines A-A′, B-B′, C-C′, D-D′ and E-E′ in FIG. 15.

### DETAILED DESCRIPTION OF EXAMPLE EMBODIMENTS

Hereinafter, example embodiments will be explained in detail with reference to the accompanying drawings.

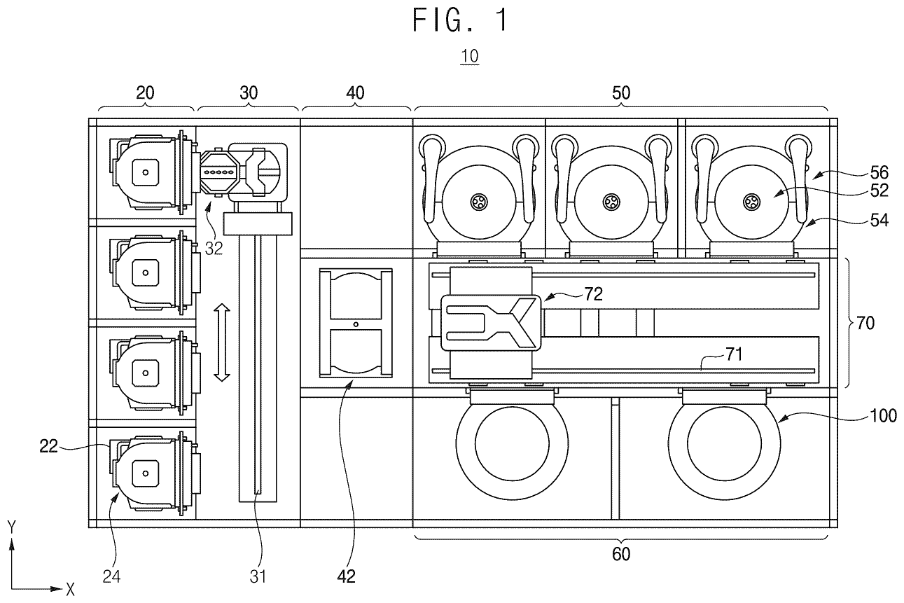

FIG. 1 is a plan view illustrating a substrate processing system in accordance with example embodiments.

Referring to FIG. 1, a substrate processing system 10 may include a load port 20 and an index module 30 configured to load and unload substrates such as wafers, and a process module disposed in one side of the index module 30 and configured to sequentially perform semiconductor processes on the wafers. The load port 20, the index module 30 and the process module may be arranged along a first direction (X direction). The process module may include a buffer chamber 40, a first process chamber 50, a second process chamber 60 and a transfer chamber 70.

In example embodiments, the substrate processing chamber 10 may perform semiconductor processes such as a developing process, a drying process, etc., on a substrate on which a exposure process and a soft bake process have been performed. For example, the first process chamber 50 may perform a cleaning process where a chemical process, a rinse process and an organic solvent process are sequentially carried out, and the second process chamber 60 may perform a drying process using a supercritical fluid.

As illustrated in FIG. 1, the load port 20 may include a support plate 22 for supporting a wafer carrier 24 (FOUP, a front opening unified pod) where a plurality of wafers W are accommodated. The load port 20 may be a port on which the substrate is loaded or unloaded, and a plurality of the support plates 22 may be arranged in the load port 20 along a second direction (Y direction) perpendicular to the first direction.

The index module 30 may include an indexer robot 32 that is movable along an index rail 31 extending in the Y direction within an index frame. The indexer robot 32 may transfer the wafer between the wafer carrier 24 on the support plate 22 and the process module. The indexer robot 32 may include a base, a robot hand and a vertical guide. The base may be installed to be movable in the Y direction along the index rail 31, the vertical guide may extend in a vertical direction on the base, and the robot hand may be installed to be movable in the vertical direction along the vertical guide.

The process module may be disposed in one side of the index module 30. The buffer chamber 40 may be disposed in one side of the index frame of the index module 30. The buffer chamber 40 may include a plurality of buffer portions 42 that temporarily stores a plurality of wafers respectively. The plurality of buffer portions 42 may be spaced apart from each other in the vertical direction. The buffer portion 42 may include a support plate for supporting the wafer. The buffer chamber 40 may include a buffer robot that is disposed in one side of the buffer portions 42 and is configured to transfer the substrate between the buffer portions 42.

The transfer chamber 70 may extend from the buffer chamber 40 in a direction parallel with the X direction. The first process chambers 50 may be disposed in a first side of the transfer chamber 70. The second process chambers 60 may be disposed in a second side of the transfer chamber 70 opposite to the first side. The first process chambers 50 may be disposed along the X direction. The second process chambers 60 may be disposed along the X direction. The first process chambers 50 may include a plurality of cleaning apparatuses stacked in multiple stages in the vertical direction. The second process chambers 60 may include a plurality of substrate processing apparatuses 100 stacked in multiple stages in the vertical direction.

The buffer chamber 40 may provide a space where wafers to be transferred from the index module 30 to the first process chamber 50 and wafers to be transferred from the second process chamber 60 to the index module 30 temporarily stay. The developing process may be performed on a wafer in the first process chamber 50. In the first process chamber 50, the developing process may be performed on the wafer on which an exposure process has been performed. In the second process chamber 60, the drying process may be performed on the wafer on which the developing process has been performed.

The transfer chamber 70 for transferring a wafer may be disposed between the first process chamber 50 and the second process chamber 60. A transfer robot 72 may transfer the wafer while moving along a transfer rail 71 extending in the X direction. The transfer robot 72 may be installed to be movable in a vertical direction along a vertical guide.

The transfer robot 72 may transfer the wafer placed in the buffer chamber 40 to the first process chamber 50. The transfer robot 72 may transfer the wafer on which the developing process has been performed in the first process chamber 50, to the second process chamber 60. The transfer robot 72 may transfer the wafer W on which the developing process has been performed in the second process chamber 60, to the buffer chamber 40.

In example embodiments, the plurality of first process chambers 50 may be arranged in the X direction. Types of developers used in each of the first process chambers 50 may be different from each other. As an example, a negative tone developer may be used as the developer. The developer may include n-Butyl Acetate. The first process chamber 50 may include a developing apparatus that is configured to perform the developing process to apply a developer on a wafer on which an exposure process has been performed.

The developing apparatus may spray a developer on an exposed photoresist layer on the substrate while supporting and rotating the substrate such as a wafer W. The developing apparatus may include a substrate support 52, a bowl assembly 54 and a chemical solution ejector 56. When the substrate support 52 rotates the wafer W at a desired speed, the chemical solution ejector 56 may spray the developer on a top surface of the wafer W. When the wafer W rotates, the bowl assembly 54 may collect and discharge the developer scattered from the wafer W.

The plurality of second process chambers 60 may be arranged in the X direction. The second process chamber 60 may perform the drying process to supply a high pressure fluid on the wafer coated with the developer. For example, the developing process may be performed on the wafer W in the first process chamber 50 and the drying process may be performed in the second process chamber 60.

Alternatively, in the first process chamber 50, a chemical process, a rinse process and a first drying process may be sequentially performed on the wafer W and, in the second process chamber 60, a second drying process may be performed. In this case, the first drying process may be performed using an organic solvent and the second drying process may be performed using a supercritical fluid. An isopropyl alcohol IPA solution may be used as the organic solvent, and carbon dioxide CO₂ may be used as the organic solvent. Alternatively, the first drying process in the first process chamber 50 may be omitted.

The arrangement of the load port, the index module and the process module and the arrangement and number of the first and second process chambers are provided as examples, and thus, it may be understood that it is not limited thereto.

Hereinafter, the substrate processing apparatus 100 of the second process chamber 60 will be described in detail.

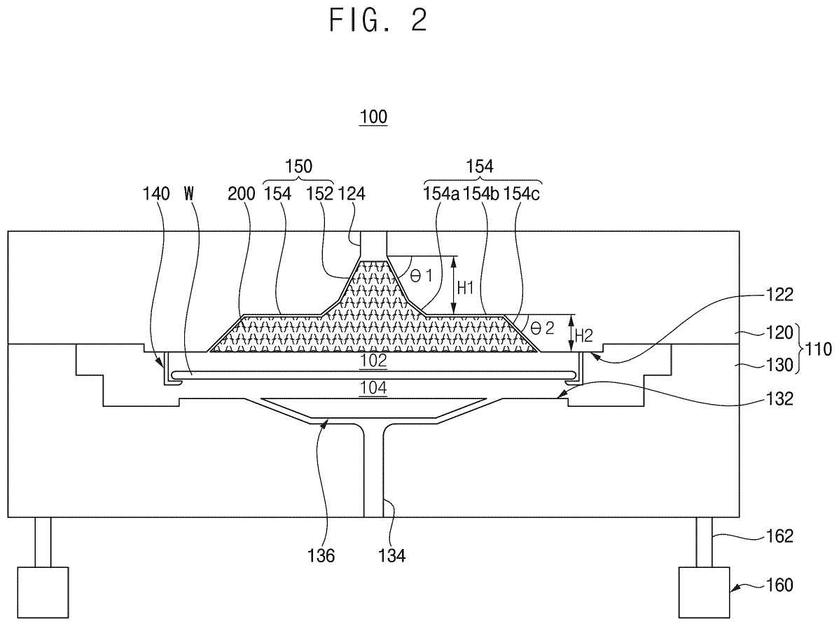

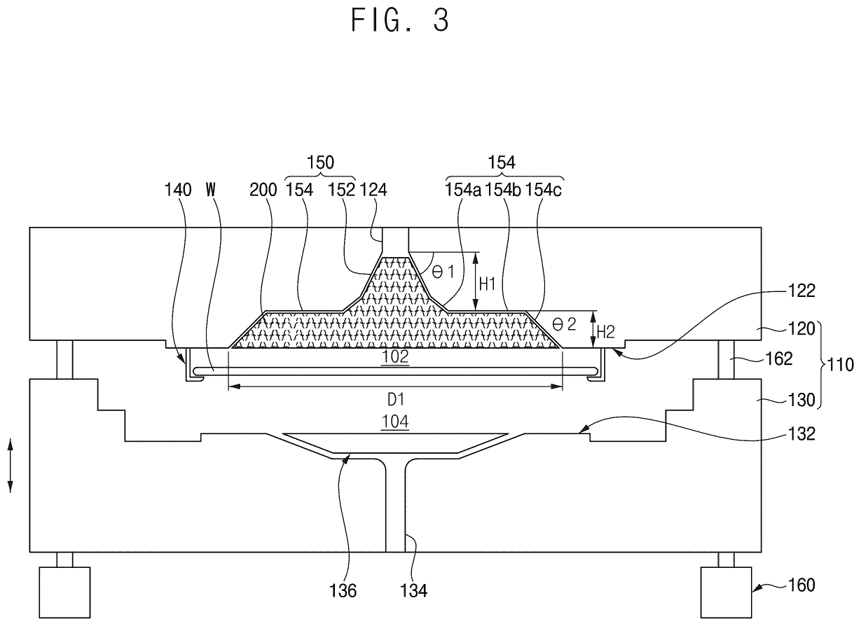

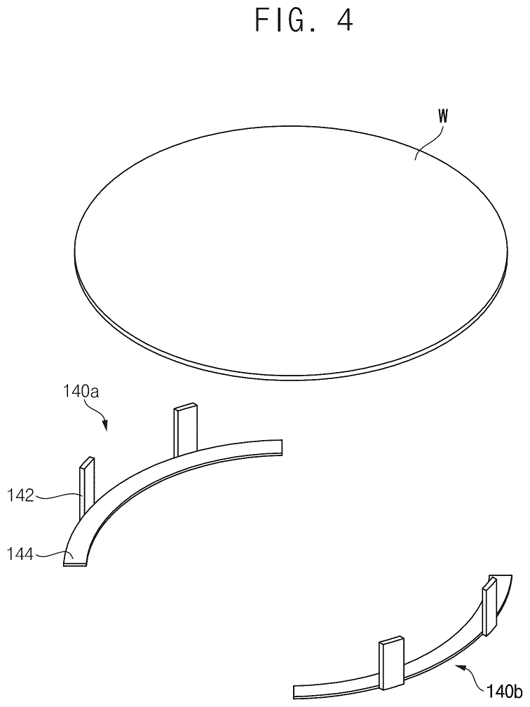

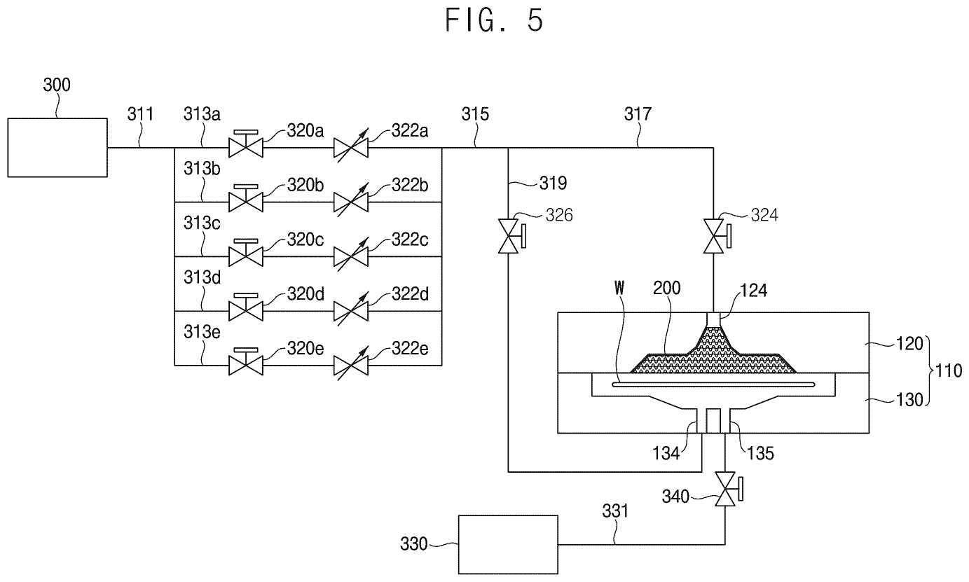

FIG. 2 is a cross-sectional view illustrating a substrate processing apparatus in accordance with example embodiments. FIG. 3 is a cross-sectional view illustrating a chamber of the substrate processing apparatus in FIG. 2, wherein the chamber is in an open state. FIG. 4 is a perspective view illustrating a substrate support of the substrate processing apparatus in FIG. 2. FIG. 5 is a block diagram illustrating a gas supply of the substrate processing apparatus in FIG. 2.

Referring to FIGS. 2 to 5, a substrate processing apparatus 100 may include a chamber 110, a substrate support 140, an upper supply port 124, an exhaust port 135 and a fluidic baffle 200. In addition, the substrate processing apparatus 100 may further include a lower supply port 134 and a blocking plate 136.

In example embodiments, the substrate processing apparatus 100 may be an apparatus that is configured to support a substrate such as a wafer W and process the substrate by a supercritical process using a supercritical fluid. The substrate processing apparatus 100 may dry the substrate W on which the developing process has been completed, by using the supercritical fluid. The supercritical fluid may include carbon dioxide (CO₂) in a supercritical state.

For example, the supercritical process may include a cleaning process using a supercritical fluid, a drying process, an etching process, etc. The supercritical fluid may include a material having diffusivity, viscosity and surface tension such as a gas and having a temperature and pressure above a critical point where a material has liquid-like solubility. For example, the supercritical fluid is carbon dioxide (CO₂), water (H₂O), methane (CH₄), ethane (C₂H₆), propane (C₃H₈), ethylene (C₂H₄), propylene (C₃H₆), methanol (CH₃OH), ethanol (C₂H₅OH), sulfur hexafluoride (SF₆), acetone (C₃H₆O), etc.

As illustrated in FIG. 3, the chamber 110 may provide a space for drying a substrate. The space may include a process region 102 and a buffer region 104. The process region 102 may be a region containing a liquid solvent on the substrate W and the buffer region 104 may be a region under the substrate W.

The chamber 110 may include an upper chamber 120 and a lower chamber 130. The upper chamber 120 may include a lower surface 122. The lower surface 122 of the upper chamber 120 may serve as an upper wall of the chamber 110. The lower chamber 130 may include an upper surface 132. The upper surface 132 of the lower chamber 130 may serve as a lower wall of the chamber 110.

As illustrated in FIGS. 2 and 3, the upper chamber 120 and the lower chamber 130

may be moved relatively by a drive mechanism 160 to be engagable with each other so as to be switchable between a closed position for closing the chamber 110 and an open position for opening the chamber 110. For example, at least one of the upper chamber 120 and the lower chamber 130 may move upward and downward along a lifting rod 162 to be coupled with or separated from each other. In the open position of the chamber 110, the substrate W may be loaded/unloaded into/from the chamber. In the closed position of the chamber 110, a supercritical drying process of the substrate W may be performed.

The substrate support 140 may be disposed in the chamber 110 and may support the substrate W when the substrate W is loaded in the chamber 110. The substrate support 140 may support the substrate W at the open position of the chamber 110 when the substrate W is loaded/unloaded in the chamber. Additionally, the substrate support 140 may be disposed in the chamber 110 and support the substrate W when the substrate W is processed in the chamber. The substrate support 140 may support the substrate W at the closed position of the chamber 110 when a supercritical fluid process is performed on the substrate W.

As illustrated in FIG. 4, the substrate support may include a pair of support members 140a and 140b that are configured to support the substrate W at a position spaced apart from the lower surface 122 of the upper chamber 120 by a predetermined distance. Each of the support members 140a and 140b may include a vertical rod 142 that extends downward from the lower surface 122 of the upper chamber 120 and a horizontal rod 144 that extends horizontally from one end of the vertical rod 132. Accordingly, the pair of support members 140a and 140b may support edge regions of the substrate W, respectively.

In example embodiments, the upper supply port 124 may be provided in the upper chamber 120. The upper supply port 124 may be provided in a central region of the upper chamber 120 to extend in a vertical direction. The supercritical fluid may be supplied to the process region 102 positioned above the substrate W through the upper supply port 124.

A recess 150 may be provided in the lower surface 122 of the upper chamber 120 to extend radially from an outlet of the upper supply port 124. The recess 150 may have a diffuser shape to induce flow of the supercritical fluid flowed from the outlet of the upper supply port 124 along the radial direction. A bottom surface of the recess 150 may be formed to be inclined downwardly such that a distance from the substrate W gradually decreases from the central region of the upper chamber 120 to a peripheral region of the upper chamber 120.

The recess 150 may include a first recess 152 and a second recess 154 in communication with the first recess 152. The first recess 152 may be in fluid communication with the upper supply port 124 and may have a first cone shape. The second recess 154 may have a second cone shape. The first recess 152 may have a first depth H1, and the second recess 154 may have a second depth H2. The first depth H1 may be equal to or greater than the second depth H2. The first depth H1 of the first recess 152 and the second depth H2 of the second recess 154 may be determined in consideration of a thickness of the fluidic baffle 200 disposed in the recess 150.

A sidewall of the first recess 152 may extend obliquely at a first angle θ1 with respect to a plane parallel to the lower surface 122 of the upper chamber 120, and a sidewall of the second recess 154 may obliquely extend at a second angle θ2. The first angle θ1 may be greater than the second angle θ2. For example, the first angle θ1 and the second angle θ2 may be within a range of 10 degrees to 70 degrees.

The second recess 154 may include a horizontal extension portion 154b that extends radially from an outlet of the first recess 152 in a direction parallel to an upper surface of the substrate W and an inclined extension portion 154c that extends obliquely at the second angle θ2 from the horizontal extension portion 154b. The inclined extension portion 154c may extend from the lower surface 122 of the upper chamber 120 toward the central region of the upper chamber 120. The second recess 154 may further include a connection portion 154a that connects the outlet of the first recess 152 and the horizontal extension portion 154b and extends obliquely at a specific angle.

The recess 150 may have a shape recessed from the lower surface 122 of the upper chamber 120 to provide an accommodation space. As will be described later, the fluidic baffle 200 may be disposed in the accommodation space of the recess 150. A diameter D1 of the recess 150 may be within 15% to 110% of a diameter of the substrate W. The diameter D1 of the recess 150 may be within a range of 50 mm to 315 mm.

The lower supply port 134 may be provided in the lower chamber 130. The lower supply port 134 may be provided in a central region of the lower chamber 130 to extend vertically. The supercritical fluid may be supplied to the buffer region 104 positioned below the substrate W through the lower supply port 134.

The exhaust port 135 may be provided in the lower chamber 130. The exhaust port 135 may be provided in the central region of the lower chamber 130 adjacent to the lower supply port 134 to extend vertically. The exhaust port 135 may discharge a fluid used in the supercritical fluid process from the chamber 110. The discharged fluid may include a supercritical fluid in which an organic solvent is dissolved. The fluid discharged from the exhaust port 135 may be supplied to a regeneration apparatus to be separated into a supercritical fluid and an organic solvent.

In example embodiments, the fluidic baffle 200 may be disposed in the recess 150 of the upper chamber 120 between the upper supply port 124 and the substrate W. The fluid baffle 200 may be a 3D printed porous streamlined structure. The fluid injected into the fluid baffle 200 from the upper supply port 124 may flow along several passages in the porous structure. A flow rate and pressure of the fluid flowing through each passage in the fluid baffle 200 may be reduced, and the fluid baffle 200 may distribute the fluid outward from the center of the substrate W. A detailed configuration of the fluid baffle will be described later.

In example embodiments, the blocking plate 136 may be disposed between the upper surface 132 of the lower chamber 130 and the substrate W. The blocking plate 136 may be installed to be spaced apart from the upper surface 132 of the lower chamber 130 by a predetermined distance. The blocking plate 136 may be fixedly provided on the upper surface 132 of the lower chamber 130 by a support rod (not illustrated). The blocking plate 136 may include a plate having a predetermined thickness that occupies a predetermined space within the buffer region 104. The blocking plate 136 may block the supercritical fluid from being directly injected onto a backside surface of the substrate W from the lower supply port 134.

In addition, a volume of the buffer region 104 may be reduced by the blocking plate 136. The volume of the buffer region 104 may be less than a volume of the process region 102. Accordingly, an amount of the supercritical fluid in the buffer region 104 under the substrate W may be relatively less than an amount of supercritical fluid in the process region 102 above the substrate W. Since the block plate 136 is arranged in the buffer space under the substrate W, the amount of the supercritical fluid used in the drying process may be reduced while maintaining process performance, to thereby reduce process time.

In example embodiments, the substrate processing apparatus may include a heater disposed in at least one of the upper chamber 120 and the lower chamber 130 of the chamber 110. The heater may heat the inside of the chamber to maintain the temperature of the supercritical fluid supplied into the chamber above the critical temperature.

As illustrated in FIG. 5, the substrate processing apparatus 100 may include a fluid supply configured to supply a high pressure fluid into the chamber 110 and an exhaust portion configured to discharge the fluid from the chamber 110.

The fluid supply may include a fluid supply tank 300, a front supply line connected to the fluid supply tank 300, first to fifth parallel lines 313a, 313b, 313c, 313d and 313e connected in parallel to the front supply line 311, a rear supply line 315 connected to the first to fifth parallel lines 313a, 313b, 313c, 313d and 313e, and an upper supply line 317 and a lower supply line 319 branched off from the rear supply line 315. The upper supply line 317 may be in fluid communication with the upper supply port 124 and the lower supply line 319 may be in fluid communication with the lower supply port 134.

In the first to fifth parallel lines 313a, 313b, 313c, 313d and 313e, first to fifth opening/closing valves 320a, 320b, 320c, 320d and 320e and first to fifth flow control valves 322a, 322b, 322c, 322d and 322e may be installed, respectively. A first upper opening/closing valve 324 may be installed in the upper supply line 317, and a second upper opening/closing valve 326 may be installed in the lower supply line 319.

The first to fifth opening/closing valves 320a, 320b, 320c, 320d and 320e may control flowing of fluids flowing through the first to fifth parallel lines 313a, 313b, 313c, 313d and 313e, respectively. The first to fifth flow control valves 322a, 322b, 322c, 322d and 322e may control flow rates of the fluids flowing through the first to fifth parallel lines 313a, 313b, 313c, 313d and 313e, respectively. For example, each of the first to fifth flow control valves 322a, 322b, 322c, 322d and 322e may include a mass flow controller MFC. The first upper opening/closing valve 324 may control flowing of a fluid flowing through the upper supply line 317, and the second upper opening/closing valve 326 may control flowing of a fluid flowing through the lower supply line 319.

The exhaust portion may include an exhaust apparatus 330 connected to the exhaust port 135 of the lower chamber 130 through an exhaust line 331. An exhaust opening/closing valve 340 may be installed in the exhaust line 331. The exhaust apparatus 330 may include a vacuum pump to exhaust the fluid from the chamber 110.

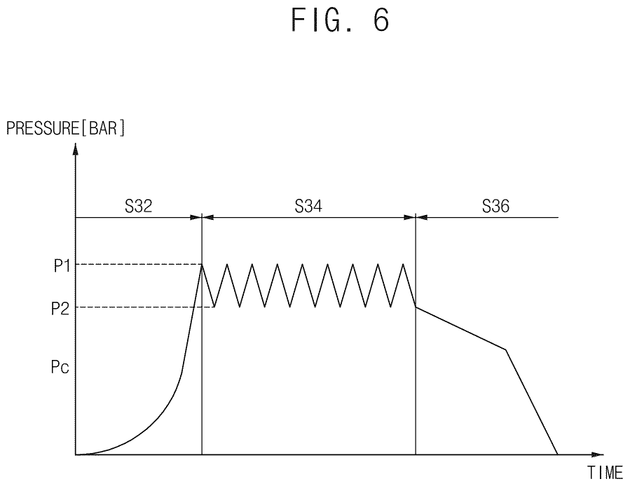

FIG. 6 is a graph illustrating a change in pressure inside a chamber while a drying process is performed in the substrate processing apparatus in FIG. 2.

Referring to FIG. 6, a drying process performed by the substrate processing apparatus 100 may include a pressurization step S32, a mixing step S34 and a depressurization step S36. The pressurization step S32, the mixing step S34 and the depressurization step S36 may be sequentially performed in the substrate processing apparatus 100.

First, the pressurization step S32 may be performed to increase pressure inside the chamber 110 to predetermined pressure P1. The pressurization step S32 may be performed after the substrate W is loaded into the chamber 110. The gas supply may supply fluid into the chamber 110 to increase the pressure of the chamber to the first pressure P1.

For example, after the substrate W on which a developer is sprayed is loaded on the substrate support in the chamber 110, the first opening/closing valve 320a may be turned on and may supply fluid at a flow rate of 0.1 g/s to 0.5 g/s. The first opening/closing valve 320a may be turned on for 10 seconds to 30 seconds. Then, the second to fifth open/close valves 320b, 320c, 320d and 320e may be sequentially turned on to supply fluid. At this time, a speed of the supplied fluid may be gradually increased. For example, when the second opening/closing valve 320b is turned on, fluid may be supplied at a flow rate of 0.5 g/s to 2 g/s, when the third opening/closing valve 320c is turned on, fluid may be supplied at a flow rate of 3 g/s to 10 g/s, and when the fourth opening/closing valve 320d is turned on, the pressure inside the chamber 110 may increase to the first pressure P1. For example, the first pressure P1 may be within a range of 80 bars to 150 bars.

Then, the mixing step S34 may be performed to periodically change the pressure inside the chamber 110 within a certain period range. In the mixing stage S34, in order to efficiently remove the developer, pressurization and depressurization of the high pressure fluid may be repeated to form a mixed phase of the developer and the high pressure fluid.

For example, after increasing the pressure to the first pressure P1, the high pressure fluid inside the chamber 110 may be discharged through the exhaust portion to reduce the pressure inside the chamber 110 to a second pressure P2. The second pressure P2 may be within a range of 75 bars to 90 bars. Then, as the fifth opening/closing valve 320e is turned on, the fluid may be supplied at a flow rate of 5 g/s to 10 g/s to increase the pressure to the first pressure P1 again. This pressurization and decompression may be repeated one or more times depending on the amount of the applied developer. The operating sequence, the fluid supplying speed, the fluid supplying time, etc described above are provided as examples, and thus, it may be understood that it is not limited thereto.

Then, the depressurization stage S36 may be performed to decrease the pressure inside the chamber 110 to atmospheric pressure. For example, the mixed phase of the fluid inside the chamber 110 may be exhausted at a first discharge speed to decrease the pressure inside the chamber 110 to a first exhaust pressure, and the mixed phase of the fluid may be exhausted at a second discharge speed greater than the first discharge speed to decrease the pressure inside the chamber 110 to a second exhaust pressure lower than the first exhaust pressure.

Hereinafter, the fluidic baffle will be described in detail.

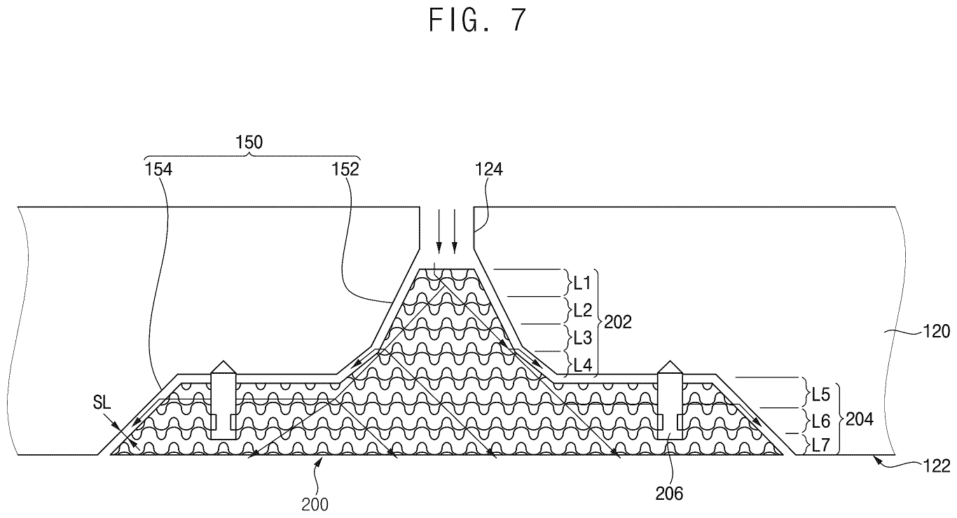

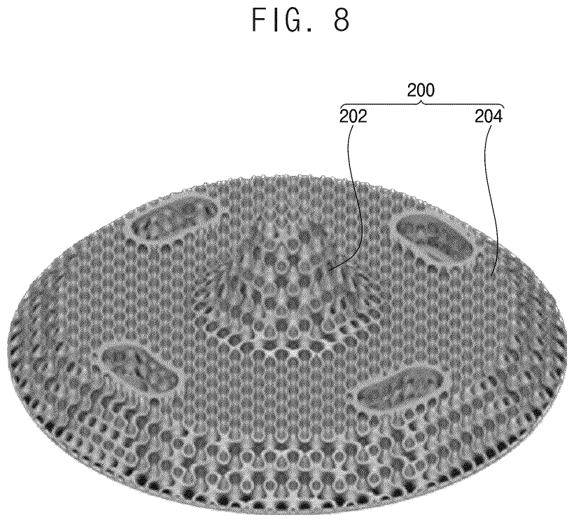

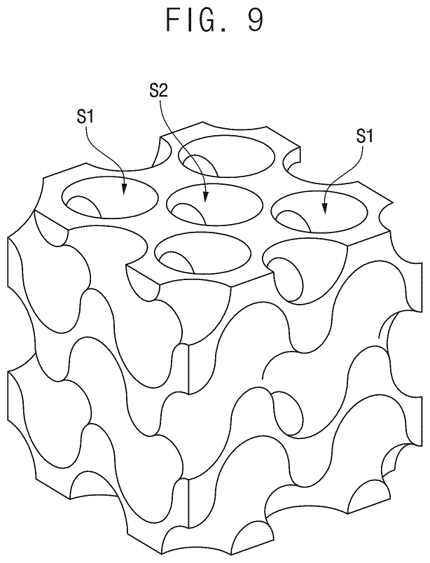

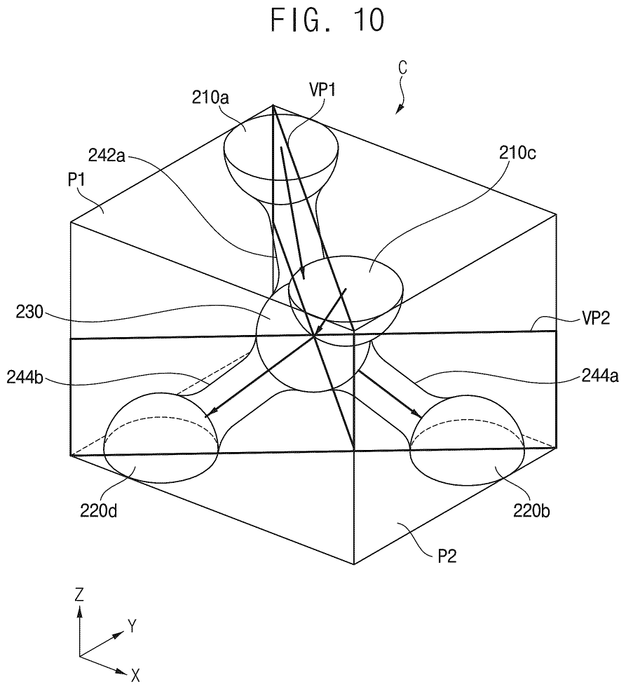

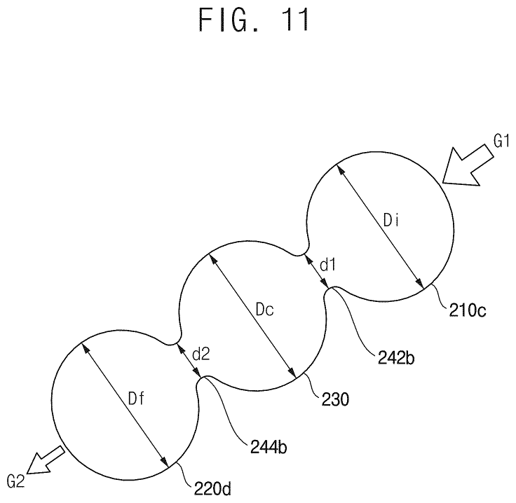

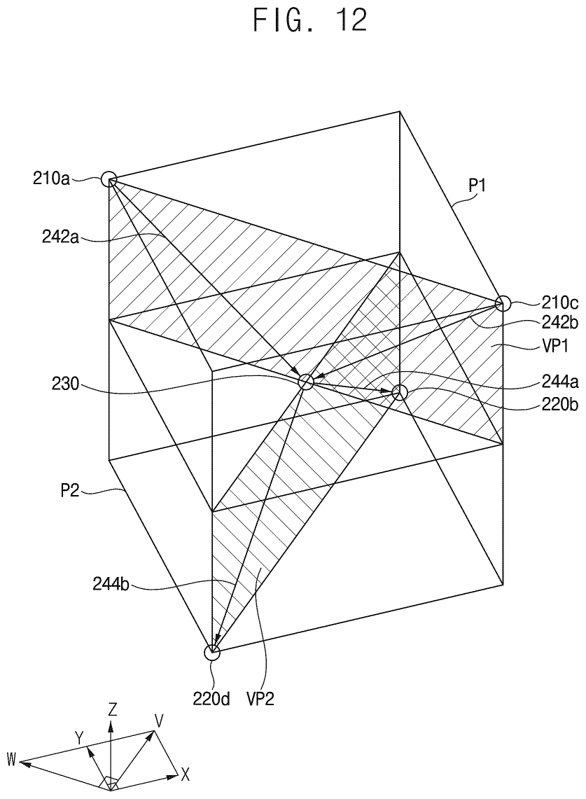

FIG. 7 is a cross-sectional view illustrating a fluidic baffle installed in the substrate processing apparatus in FIG. 2. FIG. 8 is a perspective view illustrating the fluidic baffle in FIG. 7. FIG. 9 is a perspective view illustrating a portion of the fluidic baffle in FIG. 7. FIG. 10 is a perspective view illustrating a unit cell of the fluidic baffle of FIG. 7. FIG. 11 is a cross-sectional view illustrating a fluid passage of the unit cell in FIG. 10. FIG. 12 is a view illustrating fluid flow in the unit cell in FIG. 10. FIG. 13 is a view illustrating fluid flow in a portion of the fluidic baffle of FIG. 7.

Referring to FIGS. 7 to 13, a fluidic baffle 200 may be arranged in the recess 150 that is provided in an upper wall of the chamber 110. The fluidic baffle 200 may be disposed between the upper supply port 124 in the recess 150 and the substrate W supported in the chamber 110.

In example embodiments, the fluidic baffle 200 may include unit cells C in fluid communication with each other. The unit cells C may be repeatedly arranged and evenly distributed in a space with same phases and geometric sizes. The fluidic baffle 200 may have a three-dimensional curved structure where an interior is divided into two subspaces S1 and S2 twisted with each other by an interface. For example, the unit cells C may have a lattice structure designed by Triply Periodic Minimal Surface (TPMS). The fluidic baffle 200 may be formed by a 3D printing technique. The fluidic baffle 200 may include a metal material such as iron (Fe), chromium (Cr), nickel (Ni), etc.

As illustrated in FIGS. 7 and 8, the fluidic baffle 200 may include a first cone-shaped upper baffle 202 and a second cone-shaped lower baffle 204 formed integrally with the upper baffle 202. The recess 150 may include a first recess 152 that is in fluid communication with the upper supply port 124 and has a shape corresponding to the first cone shape and a second recess 154 that is in fluid communication with the first recess 152 and has a shape corresponding to the second cone shape. The upper baffle 202 may be disposed in the first recess 152 and the lower baffle 204 may be disposed in the second recess 154. A lower end of the upper baffle 202 may be connected with a central region of an upper end of the lower baffle 204.

The fluidic baffle 200 may be fixedly installed in the upper chamber 120 by a plurality of support rods 206 that extend downward from an inner wall of the recess 150 respectively. The fluidic baffle 200 may be spaced apart from the inner wall of the recess 150 by a predetermined distance SL. The fluidic baffle 200 may be spaced apart from the inner wall of the recess 150 by at least 0.2 mm.

The fluidic baffle 200 may have a multi-layered uniform lattice structure. For example, the fluidic baffle 200 may include seven lattice layers L1, L2, L3, L4, L5, L6 and L7. The upper baffle 202 may include first to fourth lattice layers L1, L2, L3 and L4, and the lower baffle 204 may include fifth to seventh lattice layers L5, L6 and L7.

After a high pressure fluid introduced from the upper supply port 124 enters the upper portion of the fluidic baffle 200, the high-pressure fluid may be distributed on the upper surface of the substrate W through at least one of the first to seventh lattice layers L1, L2, L3, L4, L5, L6 and L7 within the fluidic baffle 200. When the high pressure fluid moves from an overlying lattice layer to an underlying lattice layer, the high pressure fluid may flow along oblique passages extending in an oblique direction. That is, there is no vertical passages extending vertically within the fluidic baffle 200, and accordingly the high pressure fluid may move in oblique directions within the fluidic baffle 200. Additionally, when the high pressure fluid moves in a horizontal direction in a same lattice layer, the high pressure fluid may move in oblique directions, for example, in a zigzag direction.

As illustrated in FIGS. 10 to 12, the unit cell C may include four first to fourth upper holes 210a, 210b, 210c and 210d provided in a first plane P1 and arranged in a quadrangular shape, four first to fourth lower holes 220a, 220b, 220c and 220d provided in a second plane P2 parallel with the first plane P1 and spaced apart from the first plane P1 in a vertical direction and arranged to overlap the first to fourth upper holes 210a, 210b, 210c and 210d, an crossover passage hole 230 provided between the first plane P1 and the second plane P2, and a branch passage 240 extending in an oblique direction between the first plane P1 and the second plane P2 and communicating at least one of the first to fourth upper holes 210a, 210b, 210c and 210d, at least one of the first to fourth lower holes 220a, 220b, 220c and 220d and the crossover passage hole 230 with each other.

The branch passage 240 of the unit cell C as the oblique passage may include first and second upper branch passages 242a and 242b communicating the crossover passage hole 230 with the first and third upper holes 210a and 210c arranged diagonally to each other, respectively, and first and second lower branch passages 244a and 244b communicating the crossover passage hole 230 with the second and fourth lower holes 220b and 220d arranged diagonally to each other, respectively.

The first and second upper branch passages 242a and 242b may be disposed in a first vertical plane VP1 perpendicular to the first plane P1, and the first and second lower branch passages 244a and 244b may be disposed in a second vertical plane VP2 perpendicular to the first plane P1 and intersecting the first vertical plane VP1. The first vertical plane VP1 and the second vertical plane VP2 may be perpendicular to each other. The first vertical plane VP1 may be parallel to W direction, and the second vertical plane VP2 may be parallel to V direction. The V direction may be a direction inclined at an angle of 45 degrees with respect to the X direction, and the W direction may be a direction perpendicular to the V direction.

The first and second upper branch passages 242a and 242b may extend at a first inclination angle with respect to the first plane P1. The first and second lower branch passages 244a and 244b may extend at a second inclination angle with respect to the second plane P2. The first and second inclination angles may be within a range of 30 degrees to 80 degrees.

As illustrated in FIG. 13, in case that first to third unit cells C1, C2 and C3 of a first lattice layer L1 are arranged along the X direction, second and third upper holes 210b and 210c of the second unit cell C2 may be respectively provided as first and fourth upper holes of the third unit cell C3 adjacent to the second unit cell C2, and second and third lower holes 220b and 220c of the second unit cell C2 may be respectively provided as first and fourth lower holes of the third unit cell C3 adjacent to the second unit cell C2. Similarly, first and fourth upper holes 210a and 210d of the second unit cell C2 may be respectively provided as second and third upper holes of the first unit cell C1 adjacent to the second unit cell C2, and first and fourth lower holes 220a and 220d of the second unit cell C2 may be respectively provided as second and third lower holes of the first unit cell C1 adjacent to the second unit cell C2.

The three-dimensional curved structure of the fluidic baffle 200 may be divided into the first and second subspaces S1 and S2 twisted with each other by an interface. Fluid entering through inlet holes of the first subspace S1 may flow through fluid passages of the first subspace S1 and then exit therefrom. Fluid entering through inlet holes of the second subspace S2 may flow through fluid passages of the second subspace S2 and then exit therefrom.

For example, the first and third upper holes 210a and 210c and the first and third lower holes 220a and 220c of the second unit cell C2 may be provided as the fluid passages of the first subspace S1 and the second and fourth upper holes 210b and 210d and the second and fourth lower holes 220b and 220d of the second unit cell C2 may be provided as the fluid passages of the second subspace S2.

As illustrated in FIG. 11, the third upper hole 210c disposed in the first plane P1 may be in fluid communication with the crossover passage hole 230 through the second upper branch passage 242b that extends diagonally, and the crossover passage hole 230 may be in fluid communication with the fourth lower hole 220d disposed in the second plane P2 through the second lower branch passage 244b that extends diagonally. The third upper hole 210c, the second upper branch passage 242b, the crossover passage hole 230, the second lower branch passage 244b and the fourth lower hole 220d may serve as at least a portion of a fluid pipe, that is, fluid passage.

A diameter Di of the third upper hole 210c, a diameter Dc of the crossover passage hole 230 and a diameter Df of the fourth lower hole 220d may be equal to each other and have a first diameter. A diameter d1 of the second upper branch passage 242b and a diameter d2 of the second lower branch passage 244b may be equal to each other and have a second diameter. The second diameter may be smaller than the first diameter. Minimum diameters of the second upper branch passage 242b and the second lower branch passage 244b may be 7 mm or less.

Pressure loss of a fluid pipe can be expressed by Fanning's equation (1) below.

$$Δ P = λ \frac{L}{D} \frac{γ {V}^{2}}{2} \qquad Equation ( 1 )$$

Here, ΔP is pressure loss [Pa], λ is a pipe friction coefficient, L is a pipe length, D is a pipe inner diameter, γ is a gas density [kg/m³] in the pipe, and V is a flow velocity [m/s] in the pipe.

The pressure loss may be proportional to a friction of a pipe, a length of a pipe and a flow velocity in a pipe and be inversely proportional to an inner diameter of a pipe. Since the upper hole, the crossover passage hole and the lower hole have a spherical shape and the volume of the fluid pipe changes due to the different diameters Di, d1, Dc, d2 and Df along a flow direction, when fluid passes through the fluid pipe of the unit cell C, a surge pressure of the supercritical fluid may be repeatedly dissipated as kinetic energy due to an increased pressure loss.

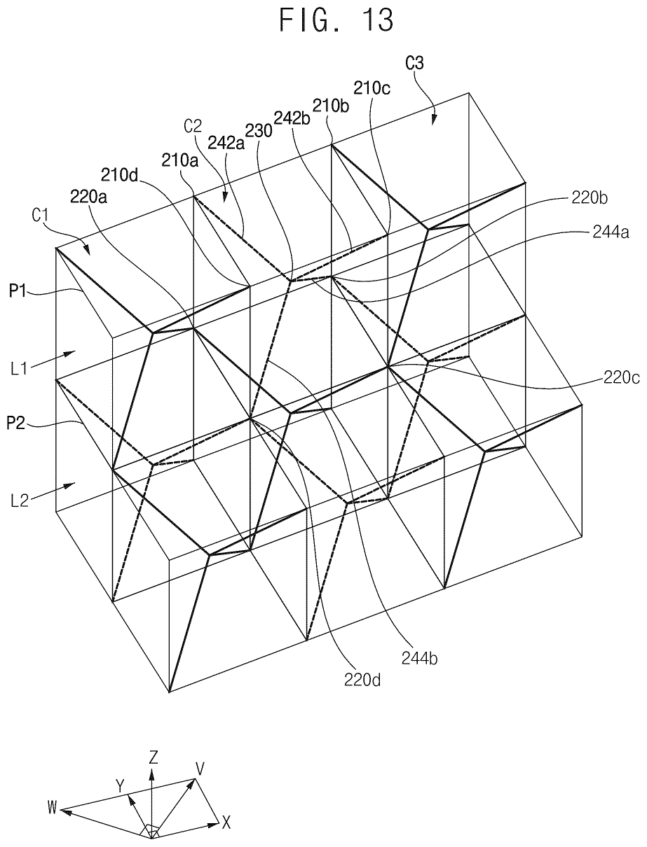

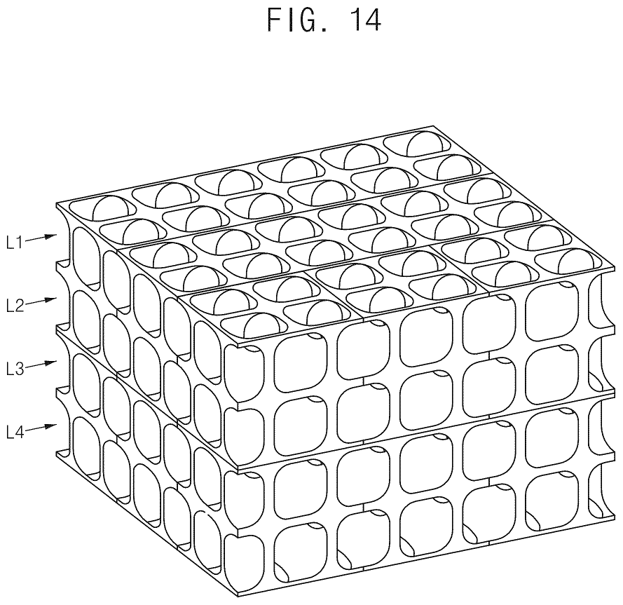

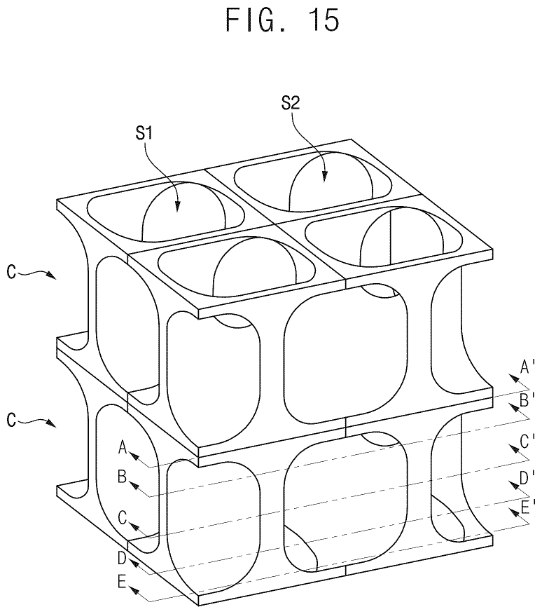

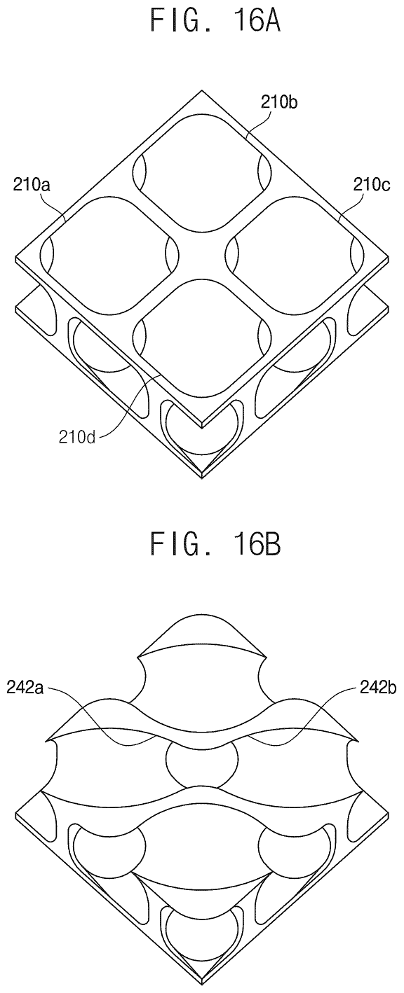

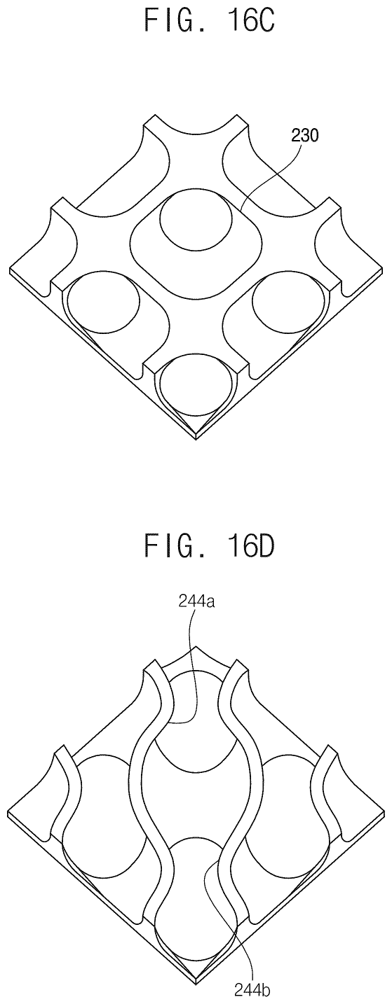

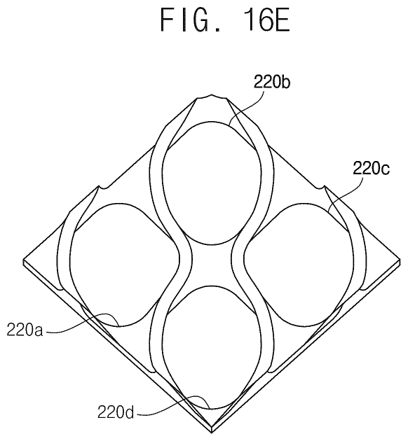

FIG. 14 is a perspective view illustrating a portion of a fluidic baffle for high pressure fluid distribution in accordance with example embodiments. FIG. 15 is a perspective view illustrating unit cells of the fluidic baffle in FIG. 14. FIGS. 16A to 16E are perspective views taken along the lines A-A′, B-B′, C-C′, D-D′ and E-E′ in FIG. 15.

Referring to FIGS. 14 to 16E, the fluidic baffle 200 may have a three-dimensional curved structure where an interior is divided into two first and second subspaces S1 and S2 twisted with each other by an interface and having triply periodic minimum curved surface TPMS. For example, the interface may have a Schwarts D surface. Alternatively, the interface may have a Gyroid surface, a Primitive surface, etc.

The unit cell C of the fluidic baffle 200 may include the first to fourth upper holes 210a, 210b, 210c and 210d disposed in a first plane P1 and arranged in a quadrangular shape, the first to fourth lower holes 220a, 220b, 220c and 220d arranged to overlap the first to fourth upper holes 210a, 210b, 210c and 210d and disposed in the second plane P2 parallel with the first plane P1 and spaced apart from the first plane P1 in the vertical direction, the crossover passage hole 230 disposed between the first plane P1 and the second plane P2, the first and second upper branch passages 242a and 242b extending in oblique directions between the first plane P1 and the second plane P2 and communicating the first and third upper holes 210a and 210c arranged diagonally to each other with the crossover passage hole 230, respectively, and the first and second lower branch passages 244a and 244b extending in oblique directions between the first plane P1 and the second plane P2 and communicating the crossover passage hole 230 with the second and fourth lower holes 220b and 220d arranged diagonally to each other, respectively.

The first and second upper branch passages 242a and 242b may be disposed in a first vertical plane perpendicular to the first plane, and the first and second lower branch passages 244a and 244b may be disposed in a second vertical plane perpendicular to the first plane and intersecting the first vertical plane. The first vertical plane and the second vertical plane may be perpendicular to each other.

As described above, the fluidic baffle 200 for high pressure fluid distribution may include the fluid pipe having the oblique passages that extend along oblique directions. As the fluid having a relatively high pressure enters the fluidic baffle 200, the fluid may move from the overlying lattice layer to the underlying lattice layer along the oblique passages.

The fluid pipe of the fluidic baffle 200 may include the upper hole, the crossover passage hole and the lower hole in fluid communication with each other through the oblique passages and having a spherical shape. Since the upper hole, the crossover passage hole, the lower hole and the oblique passages have different diameters, when the fluid passes through the fluid pipe of the fluidic baffle 200, a surge pressure of the supercritical fluid may be repeatedly dissipated as kinetic energy due to an increased pressure loss.

Accordingly, the fluidic baffle 200 may serve as an inertia relief member for relieving a flow rate of fluid supplied from an upper portion of the chamber 110 toward the substrate W. Thus, in a process of drying the developer using the supercritical fluid after treating the developer during a semiconductor photo process, an inertial force exerted on the upper surface of the substrate W by the supercritical fluid may be reduced to prevent damages such as collapse of a pattern on the substrate.

Further, the fluidic baffle 200 may include the upper baffle 202 and the lower baffle. When fluid with a relatively high pressure flows into an inlet of the upper baffle 202, because a length of a multi-channel of the upper baffle through which the introduced fluid passes is relatively longer (relatively thick thickness), a more pressure loss may occur in the upper baffle, and because the lower baffle 204 extending in a radial direction from the upper baffle has a relatively thin thickness, a pressure loss may be relatively low.

A semiconductor device manufactured by the above-described substrate processing apparatus may include a logic device or a memory device. The semiconductor device may include logic devices such as central processing units (CPUs), main processing units (MPUs), or application processors (APs), or the like, and volatile memory devices such as DRAM devices, HBM devices, or non-volatile memory devices such as flash memory devices, PRAM devices, MRAM devices, ReRAM devices, or the like.

The foregoing is illustrative of example embodiments and is not to be construed as limiting thereof. Although a few example embodiments have been described, those skilled in the art will readily appreciate that many modifications are possible in example embodiments without materially departing from the novel teachings and advantages of the present invention. Accordingly, all such modifications are intended to be included within the scope of example embodiments as defined in the claims.

What is claimed is:

1. A substrate processing apparatus, comprising:
a chamber configured to provide a space for processing a substrate;
a substrate support configured to support the substrate in the chamber;
an upper supply port provided in an upper portion of the chamber and configured to supply a supercritical fluid on an upper surface of the substrate;
a recess provided in an upper wall of the chamber, the recess having a diffuser shape whose diameter gradually increases from an outlet of the upper supply port; and
a fluidic baffle disposed in the recess between the upper supply port and the substrate, the fluidic baffle including unit cells repeatedly arranged in a space with same phases and geometric sizes and in fluid communication with each other.

2. The substrate processing apparatus of claim 1, wherein each of the unit cells includes,
upper holes disposed in a first plane and which the fluid enters;
lower holes disposed in a second plane parallel with the first plane and spaced apart from the first plane along a vertical direction;
an crossover passage hole disposed between the first plane and the second plane; and
branch passages extending along oblique directions between the first plane and the second plane, the branch passages including upper branch passages communicating the upper holes to the crossover passage hole, respectively and lower branch passages communicating the crossover passage hole to the lower holes, respectively.

3. The substrate processing apparatus of claim 2, wherein the upper branch passages include,
a first upper branch passage communicating a first upper hole to the crossover passage hole; and
a second upper branch passage communicating the crossover passage hole with a second upper hole that is arranged diagonally with the first upper hole, and
wherein the lower branch passages include,
a first lower branch passage communicating a first lower hole with the crossover passage hole; and
a second lower branch passage communicating the crossover passage hole with a second lower hole that is arranged diagonally with the first lower hole.

4. The substrate processing apparatus of claim 3, wherein the first and second upper branch passages are disposed in a first vertical plane perpendicular to the first plane, and the first and second lower branch passages are disposed in a second vertical plane perpendicular to the first plane and intersecting the first vertical plane.

5. The substrate processing apparatus of claim 4, wherein the first vertical plane and the second vertical plane are perpendicular to each other.

6. The substrate processing apparatus of claim 1, wherein the unit cells have a lattice structure designed by Triply Periodic Minimal Surface (TPMS).

7. The substrate processing apparatus of claim 6, wherein an interface of the unit cells has a Schwarts D surface.

8. The substrate processing apparatus of claim 1, wherein the fluidic baffle includes,
an upper baffle having a first cone shape; and
a lower baffle having a second cone shape and formed integrally with the upper baffle.

9. The substrate processing apparatus of claim 8, wherein the recess includes,
a first recess in fluid communication with the upper supply port and having a shape corresponding to the first cone shape; and
a second recess in fluid communication with the first recess and having a shape corresponding to the second cone shape.

10. The substrate processing apparatus of claim 1, wherein the fluidic baffle is spaced apart from an inner wall of the recess by at least 0.2 mm.

11. A substrate processing apparatus, comprising:
a chamber including an upper chamber and a lower chamber that are engageable with each other and provide a space for processing a substrate;
a substrate support configured to support the substrate in the chamber;
an upper supply port provided in the upper chamber and configured to supply a supercritical fluid on an upper surface of the substrate in the chamber;
a recess provided in an lower surface of the upper chamber, the recess having a diffuser shape whose diameter gradually increases from an outlet of the upper supply port; and
a fluidic baffle disposed in the recess between the upper supply port and the substrate, the fluidic baffle having a three-dimensional curved structure where an interior is divided into two subspaces twisted with each other by an interface and having triperiodic minimum curved surface (TPMS).

12. The substrate processing apparatus of claim 11, wherein the interface has Schwarts D surface.

13. The substrate processing apparatus of claim 11, wherein each of the two subspaces include unit cells repeatedly arranged in a space and in fluid communication with each other,
wherein each of the unit cells includes,
a first upper hole, a second upper hole, a third upper hole and a fourth upper hole disposed in a first plane and arranged in a quadrangular shape;
a first lower hole, a second lower hole, a third lower hole and a fourth lower hole arranged to overlap the first to fourth upper holes respectively and disposed in a second plane parallel with the first plane and spaced apart from the first plane in a vertical direction;
an crossover passage hole disposed between the first plane and the second plane; and
first and second upper branch passages communicating the crossover passage hole with the first and third upper holes arranged diagonally with each other, respectively, and first and second lower branch passages communicating the crossover passage hole with the second and fourth lower holes arranged diagonally with each other, respectively, the first and second upper branch passages and the first and second lower branch passages extending in oblique directions between the first plane and the second plane.

14. The substrate processing apparatus of claim 13, wherein the first and second upper branch passages are disposed in a first vertical plane perpendicular to the first plane and the first and second lower branch passages are disposed in a second vertical plane perpendicular to the first vertical plane and intersecting the first vertical plane.

15. The substrate processing apparatus of claim 14, wherein the first vertical plane and the second vertical plane are perpendicular to each other.

16. The substrate processing apparatus of claim 13, wherein the first upper hole, the third upper hole, the second lower hole, the fourth lower hole and the crossover passage hole have a first diameter, and
wherein the first upper branch passage, the second upper branch passage, the first lower branch passage and the second lower branch passage have a second diameter smaller than the first diameter.

17. The substrate processing apparatus of claim 13, wherein a minimum diameter of the second diameter is 7 mm or less.

18. The substrate processing apparatus of claim 11, wherein the fluidic baffle include at least one of iron, chromium and nickel.

19. The substrate processing apparatus of claim 11, wherein the fluidic baffle includes,
an upper baffle having a first cone shape; and
a lower baffle integrally formed with the upper baffle and having a second cone shape.

20. A substrate processing apparatus, comprising:
a chamber including an upper chamber and a lower chamber that are engageable with each other and provide a space for processing a substrate;
a substrate support configured to support the substrate in the chamber;
an upper supply port provided in the upper chamber and configured to supply a supercritical fluid on an upper surface of the substrate in the chamber;
an exhaust port provided in a lower portion of the chamber and configured to exhaust the fluid in the chamber;
a lower supply port provided in the lower portion of the chamber as adjacent to the exhaust port and configured to supply a supercritical fluid into the chamber;
a recess provided in an lower surface of the upper chamber and having a diffuser shape whose diameter gradually increases from an outlet of the upper supply port;
a fluidic baffle disposed in the recess between the upper supply port and the substrate, the fluidic baffle including unit cells repeatedly arranged in a space and in fluid communication with each other,
wherein each of the unit cells includes,
upper holes disposed in a first plane and which the fluid enters;
lower holes disposed in a second plane parallel with the first plane and spaced apart from the first plane along a vertical direction;
an crossover passage hole disposed between the first plane and the second plane; and
branch passages extending along oblique directions between the first plane and the second plane, the branch passages including upper branch passages communicating the upper holes with the crossover passage hole, respectively and lower branch passages communicating the crossover passage hole with the lower holes, respectively.
